(19) United States
(12) Patent Application Publication
(10) Pub. No.: US 2016/0190259 A1
(43) Pub. Date: Jun. 30, 2016

(54) EPITAXIAL STRUCTURE AND GROWTH THEREOF

(71) Applicant: NATIONAL TSING HUA UNIVERSITY, Hsinchu City (TW)

(72) Inventors: Keh-Yung CHENG, Hsinchu City (TW); Yu-Li WANG, Hsinchu City (TW); Chun-Hung WU, Hsinchu City (TW); Pin-Yi LEE, Hsinchu City (TW); Shao-Yen CHIU, Hsinchu City (TW)

(21) Appl. No.: 14/586,270

(22) Filed: Dec. 30, 2014

(51) Int. Cl. H01L 29/20; H01L 21/02; H01L 21/306; H01L 29/06

(52) U.S. Cl. CPC H01L 29/2003; H01L 29/0669; H01L 21/02381; H01L 21/02389; H01L 21/02378; H01L 21/02422; H01L 21/02458; H01L 21/02513; H01L 21/0254; H01L 21/02647; H01L 21/30612; H01L 21/02645

(57) ABSTRACT

The invention provides an epitaxial growth structure and a growth method thereof. The epitaxial growth structure comprises a substrate, a plurality of seeds, a plurality of nanorods and a film. The seeds arranged in an array are disposed on a surface of the substrate. The nanorods are disposed longitudinally on the seeds, respectively. The film covers horizontally on upper surfaces of the nanorods to form a substantial plane.

### BACKGROUND OF THE INVENTION

1. Field of the Invention

The invention relates to an epitaxial structure and a growth method thereof, and more particularly to an epitaxial growth structure applicable to gallium nitride (hereinafter referred to as GaN) and a growth method thereof.

2. Related Art

In the prior art, differences between lattice constants and thermal expansion coefficients of heterogeneous substrates (e.g., sapphire, Si and the like) inevitably affect the epitaxial structure quality, and cause defects and stresses of the epitaxial layers, wherein the stresses cause the warpage of the wafer and affect the precision of the manufacturing processes of the elements. For example, inadvantageous factors, such as the lattice mismatch as high as 16.2%, the thermal expansion coefficient difference of 113%, the high reactivity between atoms of Si and nitrogen (N) and the like are present between the Si substrate and GaN. In addition, when the GaN epitaxially grows on the silicon substrate, the GaN has the high defect density higher than 10⁹ cm⁻². That is, more than 10⁹ defects are present per square centimeter.

### SUMMARY OF THE INVENTION

An object of the invention is to provide an epitaxial growth structure and a growth method thereof capable of reducing the epitaxial defect density.

The invention provides an epitaxial growth structure applicable to an epitaxial growth structure of gallium nitride (GaN). The epitaxial growth structure comprises: a substrate; a plurality of seeds arranged in an array and disposed on a surface of the substrate; a plurality of nanorods disposed longitudinally on the seeds, respectively; and a film covering horizontally on upper surfaces of the nanorods to form a substantial plane.

The invention also provides a growth method of an epitaxial growth structure applicable to an epitaxial growth of gallium nitride. The method comprises: providing a silicon substrate; disposing an aluminum nitride layer on the silicon substrate, using flexible nano-imprint and then using a strong acid (wet etching) or Reactive-ion etching (RIE, dry etching) to etch the aluminum nitride layer, so that the aluminum nitride layer is formed into a plurality of seeds arranged in an array; epitaxially growing the GaN to form a plurality of nanorods longitudinally on the seeds; and epitaxially growing the GaN to form a transversal film. The film covers horizontally on upper surfaces of the nanorods to form a substantial plane.

### BRIEF DESCRIPTION OF THE DRAWINGS

FIG. 1A is a schematic view showing an epitaxial growth structure of the invention.

FIG. 1B is a schematic top view showing a substrate 101 and seeds 102 of the epitaxial growth structure of the invention.

FIG. 1C is a schematic top view showing the substrate and nanorods of the epitaxial growth structure of the invention.

FIG. 2A is a flow chart showing a growth method of the epitaxial growth structure of the invention.

FIG. 2B shows schematic view after an aluminum nitride layer is etched.

FIG. 2C is a schematic view showing GaN nanorods longitudinally formed on the seeds.

FIG. 2D is a schematic view showing GaN films transversally formed on the GaN nanorods.

FIG. 3A shows the frequency spectrum of the invention using photoluminescence measurement.

FIG. 3B shows the frequency spectrum of the invention using photoluminescence measurement at different environment temperatures.

### DETAILED DESCRIPTION OF THE INVENTION

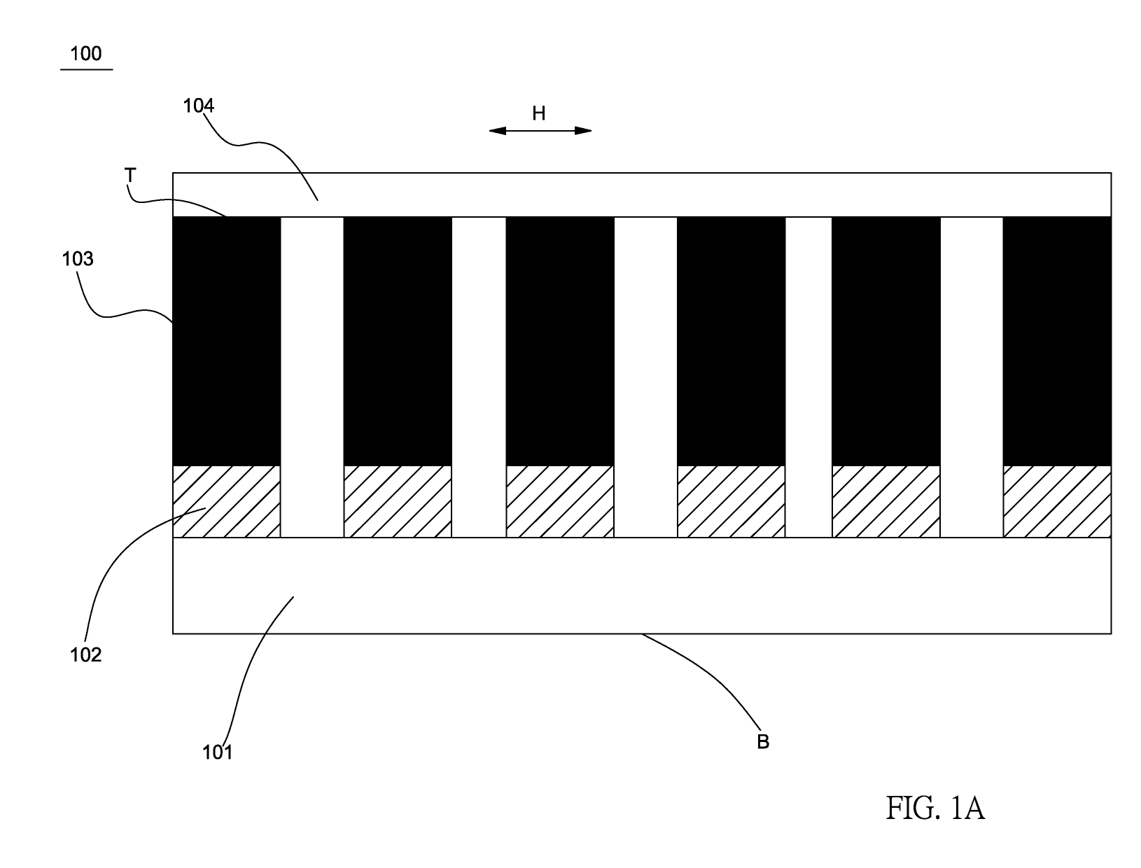

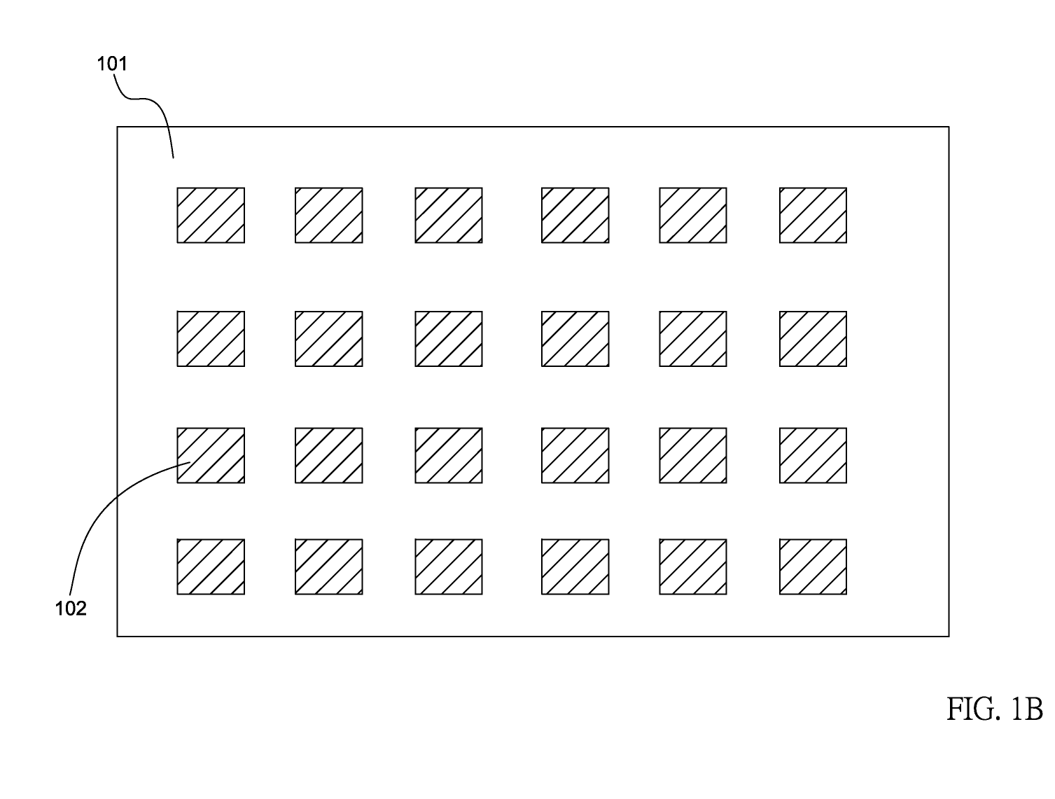

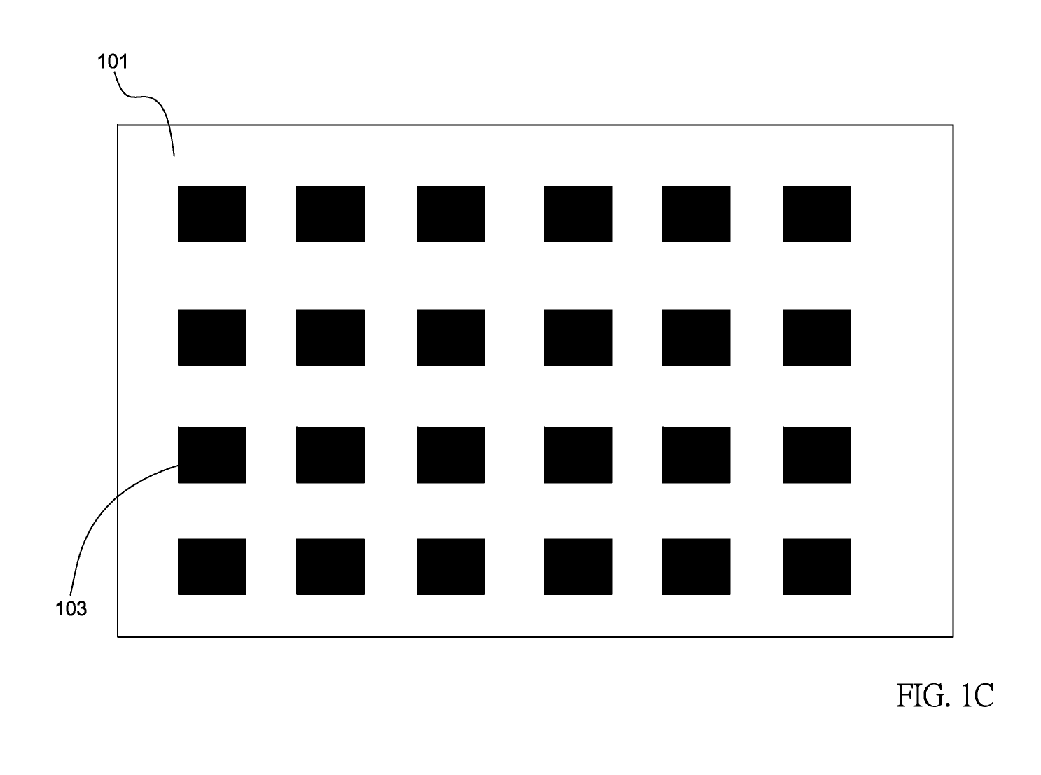

FIG. 1A is a schematic view showing an epitaxial growth structure of the invention. Referring to FIG. 1A, the structure of this embodiment is a GaN epitaxial growth structure, and the epitaxial growth structure 100 comprises a substrate 101, a plurality of seeds 102, a plurality of nanorods 103 and a film 104.

It is to be noted that the substrate 101 in this embodiment is implemented by a silicon (Si) substrate, a sapphire substrate, a gallium nitride substrate or a silicon carbide substrate.

The substrate 101 is disposed on a bottom layer B of the epitaxial growth structure 100. Next, seeds 102 are arranged in an array and disposed on a surface of the substrate 101. FIG. 1B is a schematic top view showing the substrate 101 and the seeds 102 of the epitaxial growth structure of the invention. Referring to FIGS. 1A and 1B, the seeds 102 have regular gaps in this embodiment.

FIG. 1C is a schematic top view showing the substrate and nanorods of the epitaxial growth structure of the invention. Referring to FIG. 1C, the seeds 102 in this invention is implemented by aluminum nitride (AlN), and pitches between the seeds 102 arranged in the array range from 100 to 300 nm. Then, nanorods 103 are disposed longitudinally on seeds 102, respectively, so that the long side of the nanorod 103 is substantially perpendicular to the substrate 101, and the nanorods 103 have widths ranging from 100 to 300 nm. As mentioned hereinabove, because the seeds 102 have the regular gaps, regular gaps are also present between the nanorods 103.

Finally, the film 104 covers on the upper surface T of the nanorod 103 along the horizontal direction H to form a substantial plane. In this embodiment, the nanorods 103 and the film 104 are implemented by GaN, the lengths of the nanorods 103 nanorod range from 50 to 150 nm, and the thickness of the film 104 ranges from 3 to 4 μm or from 3 to 5 μm.

It is to be noted that because the regular gaps are present between the nanorods 103, the stress generation of the film 104 can be reduced, and the breakage of the film 104 due to the stress can be avoided.

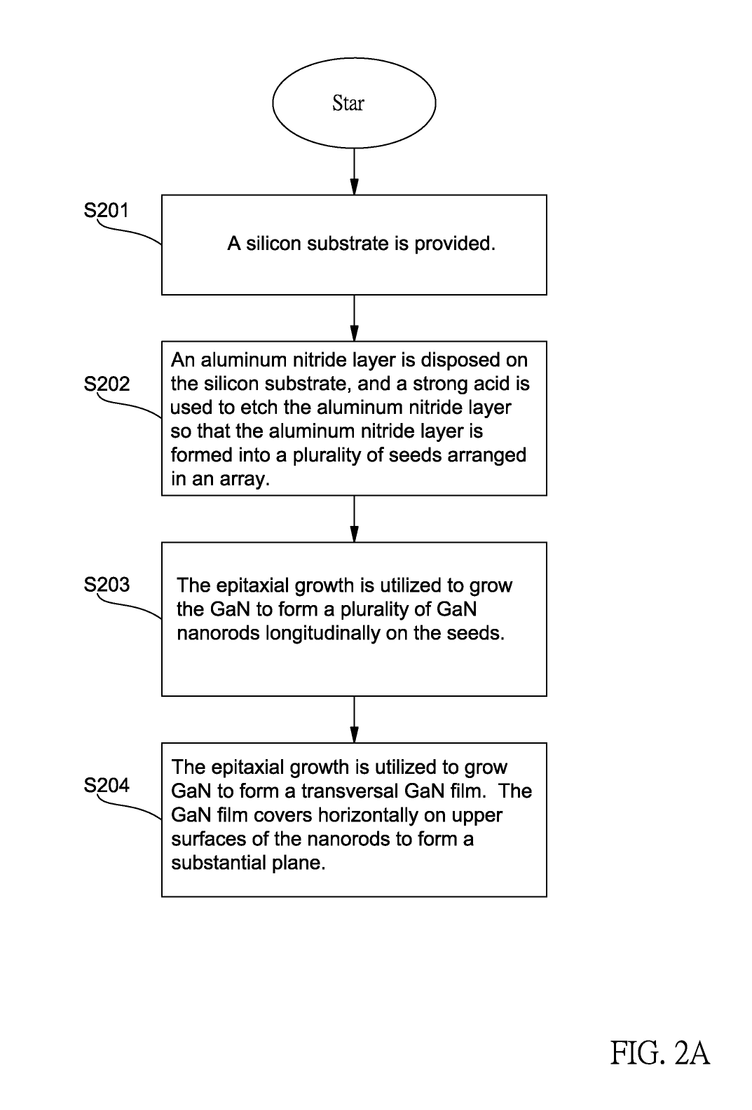

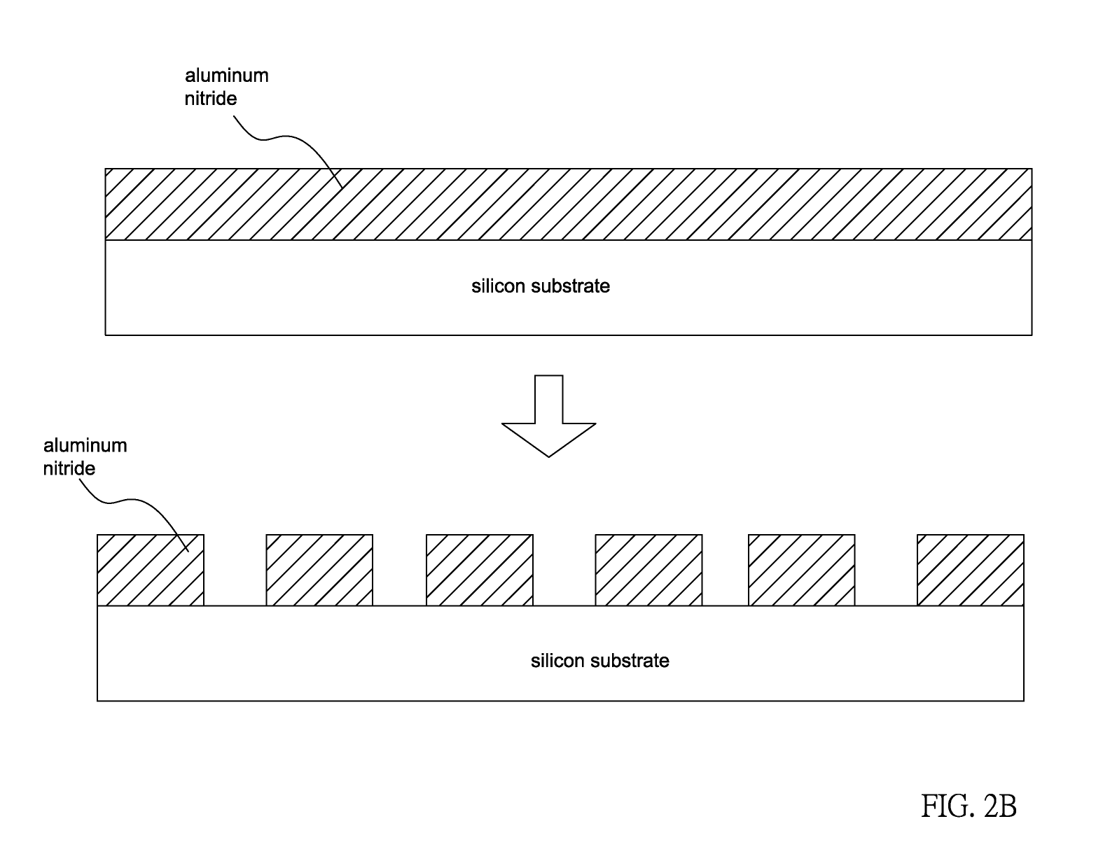

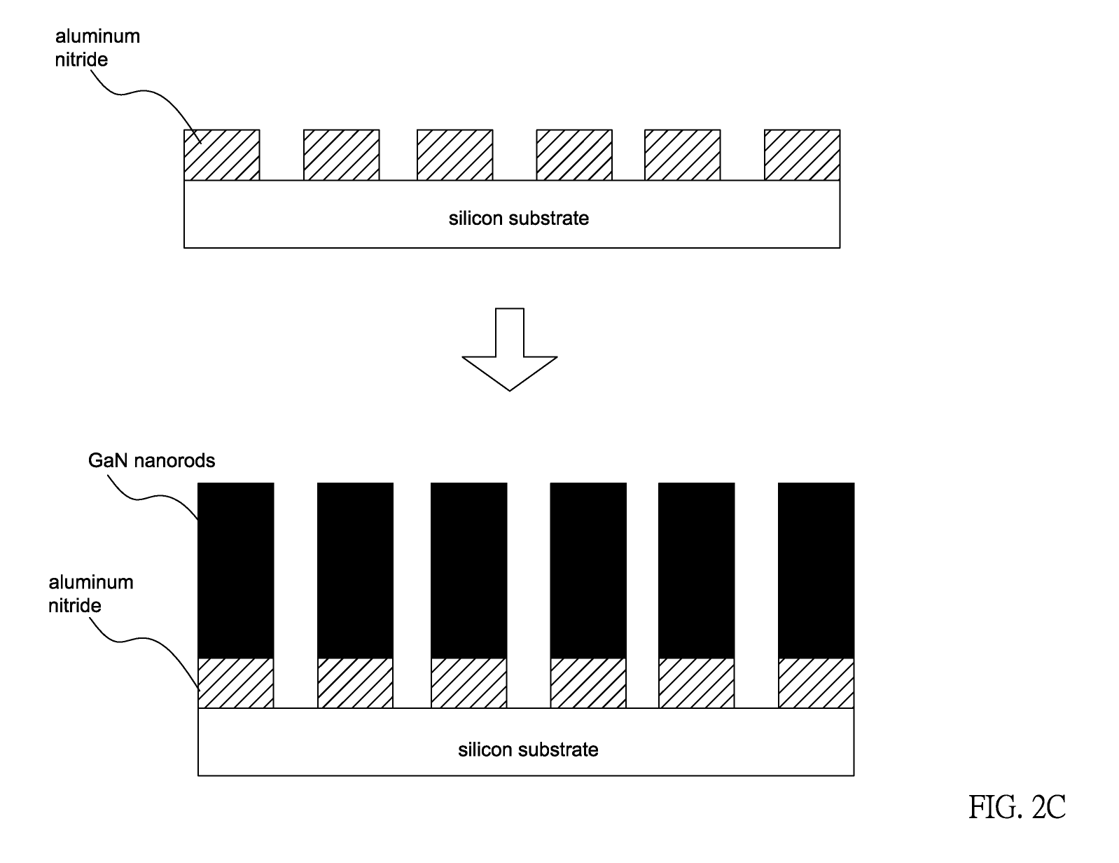

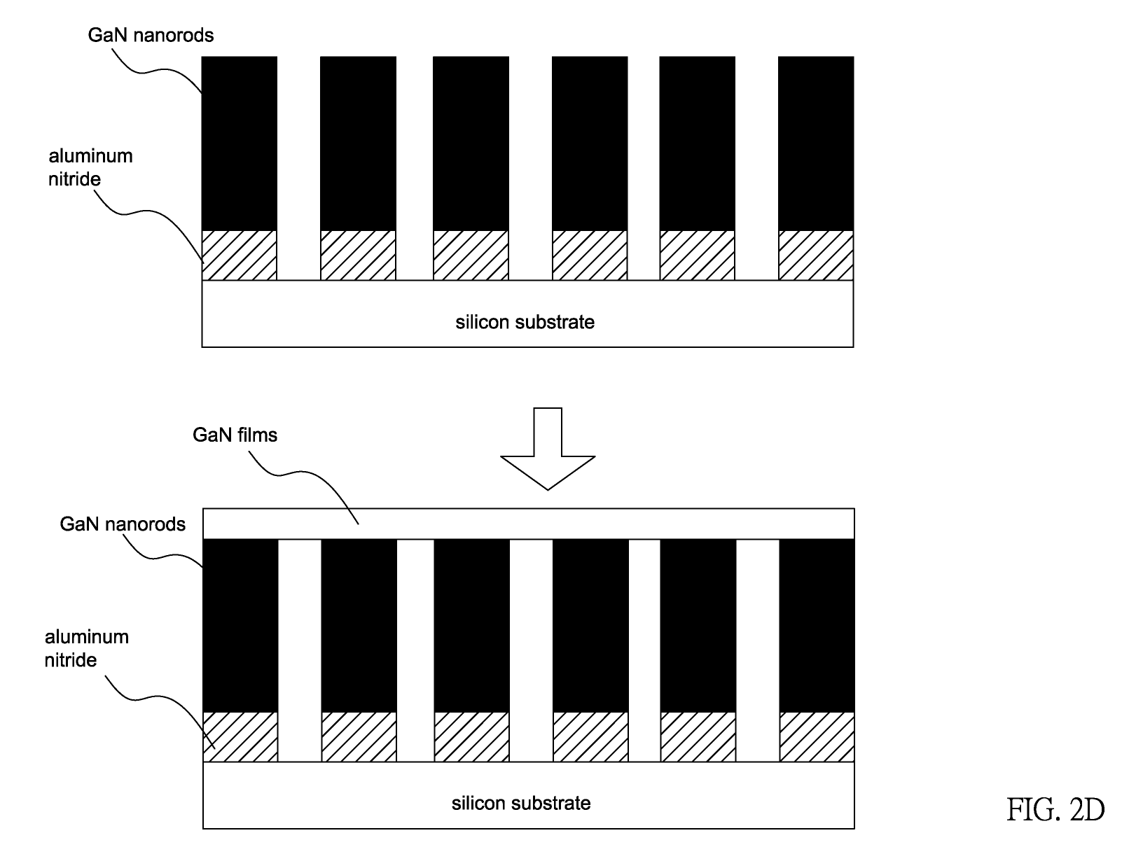

FIG. 2A is a flow chart showing a growth method of the epitaxial growth structure of the invention. FIG. 2B shows schematic view after an aluminum nitride layer is etched. Referring to FIGS. 2A and 2B, the method of this invention is applicable to epitaxial growth of GaN. The method comprises the following steps.

In step S201, a silicon substrate is provided.

In step S202, an aluminum nitride layer is disposed on the silicon substrate, and a strong acid is used to etch the aluminum nitride layer so that the aluminum nitride layer is formed into a plurality of seeds arranged in an array. In this embodiment, the strong acid is implemented by the hydrofluoric acid (HF).

In step S203, the epitaxial growth is utilized to grow the GaN to form a plurality of GaN nanorods longitudinally on the seeds, as shown in FIG. 2C, which is a schematic view showing GaN nanorods longitudinally formed on the seeds.

In step S204, the epitaxial growth is utilized to grow GaN to form a transversal GaN film. The GaN film covers horizontally on upper surfaces of the nanorods to form a substantial plane, as shown in FIG. 2D, which is a schematic view showing GaN films transversally formed on the GaN nanorods.

In this embodiment, the epitaxial growth is implemented by way of molecular beam epitaxy (MBE). In the step S203, when the GaN grows longitudinally, the nitrogen ion concentration is higher than the gallium ion concentration (N-rich), and the environment temperature is controlled at 880° C.

In one embodiment, the step S204 is implemented by way of epitaxial lateral overgrowth (ELOG) to grow the GaN into a transversal film. That is, when the GaN transversally grows, the gallium ion concentration is higher than the nitrogen ion concentration (Ga-rich), and the environment temperature is controlled at 750° C.

It is to be noted that the GaN nanorods grow on the seeds of the aluminum nitride (i.e., the regular gaps are formed upon growth of the GaN nanorods). So, when the GaN film grows, the regular gaps thereof reduce the generation of the stress of the GaN film, thereby avoiding the GaN film from breaking due to the stress.

In addition, the embodiment is described using the silicon substrate as an example, but the silicon substrate of the invention may also be replaced by a sapphire substrate, a gallium nitride substrate or a silicon carbide substrate.

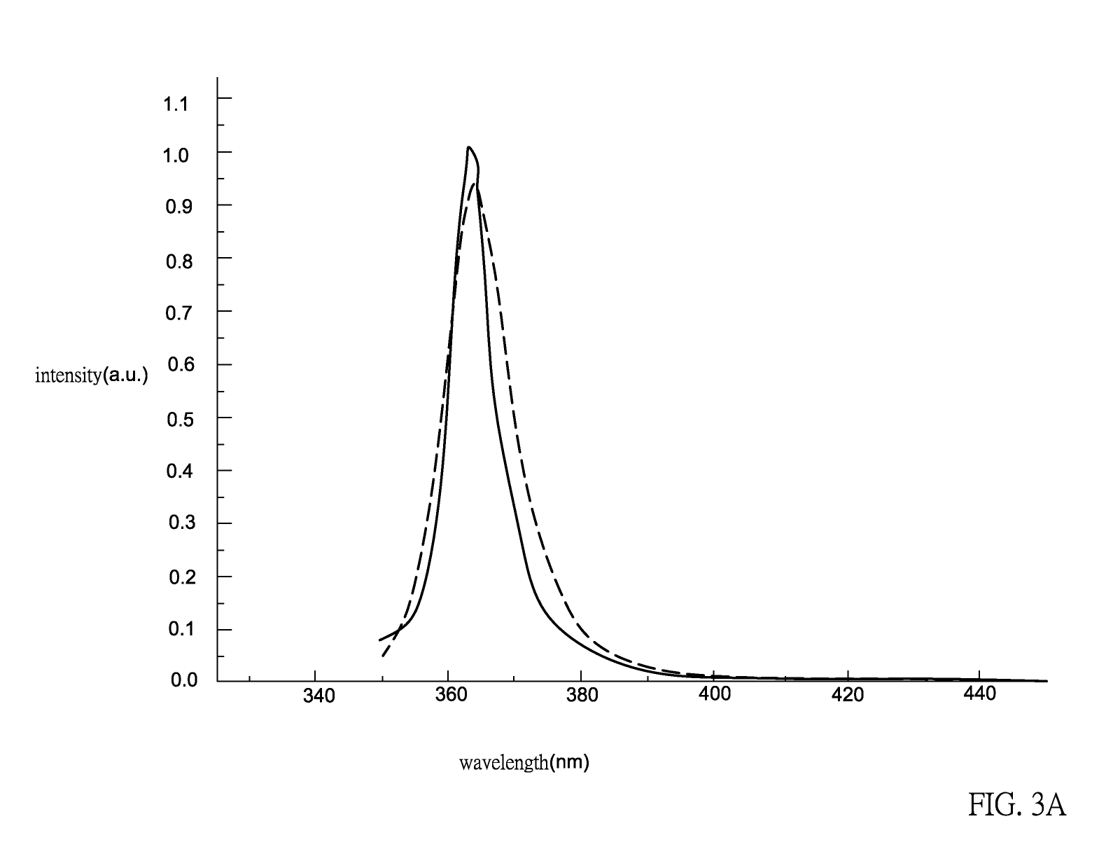

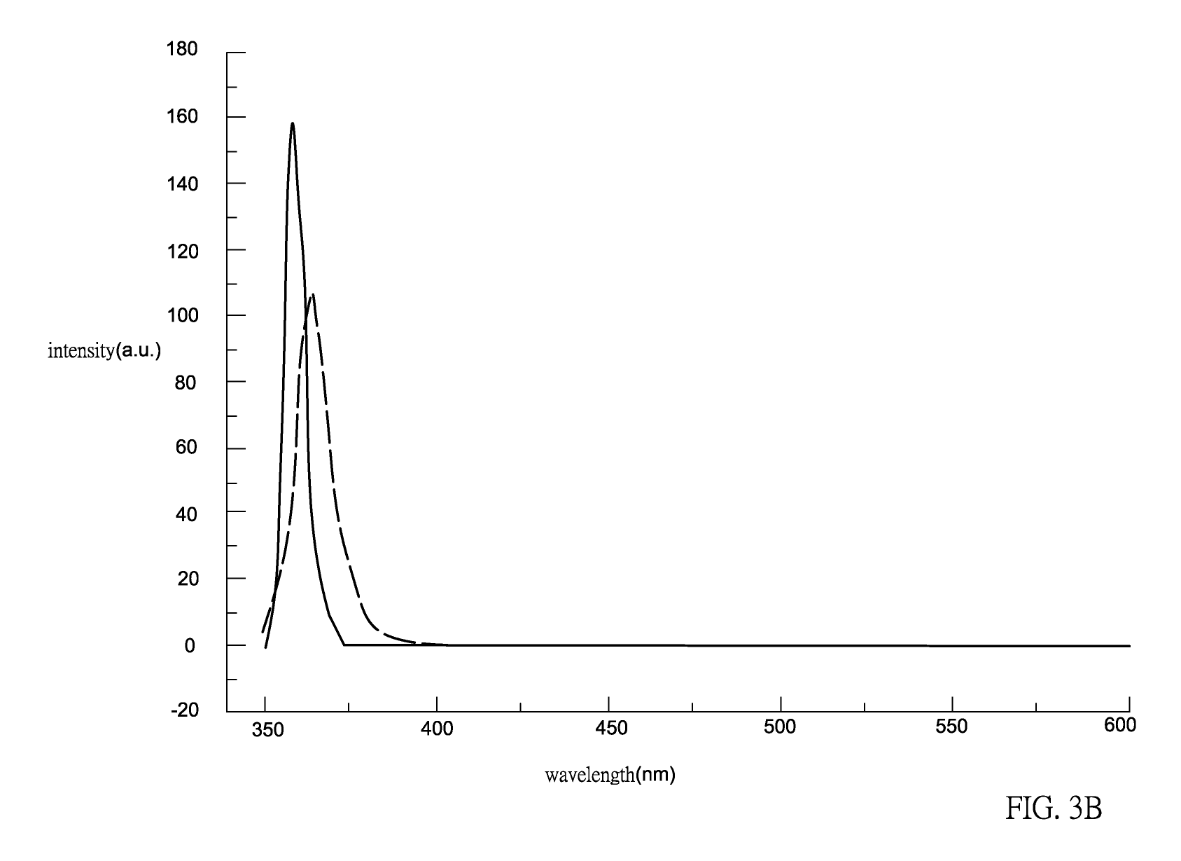

FIG. 3A shows the frequency spectrum of the invention using photoluminescence measurement. As shown in FIG. 3A, the silicon substrate of the invention is compared with the prior art sapphire substrate, wherein the solid line represents the silicon substrate, while the dashed line represents the sapphire substrate. The full width at half maximum (FWHM) of the silicon substrate of the invention is 71 meV, while the FWHM of the sapphire substrate of the prior art is 96 meV. That is, the epitaxial structure of the invention is better than that of the prior art.

FIG. 3B shows the frequency spectrum of the invention using photoluminescence measurement at different environment temperatures, wherein the dashed line represents the room temperature, while the solid line represents the absolute temperature of 77 degrees. As shown in FIG. 3B, it is obtained that the structure of the invention has the stable property at both the room temperature and the absolute temperature of 77 degrees.

In summary, the invention adopts the low-temperature growth molecular beam epitaxy method in conjunction with the array-arranged seeds to grow the GaN nanorods on the silicon substrate. The gaps between the GaN nanorods are utilized to reduce the stress caused by the lattice mismatch. Consequently, the thickness of the GaN film can be increased, and the prior art density defect can be improved.

What is claimed is:

1. An epitaxial growth structure applicable to an epitaxial growth structure of gallium nitride (GaN), the epitaxial growth structure comprising:
a substrate;
a plurality of seeds arranged in an array and disposed on a surface of the substrate;
a plurality of nanorods disposed longitudinally on the seeds, respectively; and
a film covering horizontally on upper surfaces of the nanorods to form a substantial plane.

2. The epitaxial growth structure according to claim 1, wherein the seeds are made of aluminum nitride (AlN).

3. The epitaxial growth structure according to claim 2, wherein the nanorods and the film are made of gallium nitride.

4. The epitaxial growth structure according to claim 3, wherein lengths of the nanorods range from 50 nm to 150 nm, and widths of the nanorods range from 100 to 300 nm.

5. The epitaxial growth structure according to claim 4, wherein a pitch between the seeds arranged in the array ranges from 100 to 300 nm.

6. The epitaxial growth structure according to claim 5, wherein the film has a thickness ranging from 3 to 4 μm or from 3 to 5 μm.

7. The epitaxial growth structure according to claim 1, wherein, the substrate is a silicon substrate, a sapphire substrate, a gallium nitride substrate or a silicon carbide substrate.

8. A growth method of an epitaxial growth structure applicable to an epitaxial growth of gallium nitride, the method comprising:
providing a substrate;
disposing an aluminum nitride layer on the substrate and using a strong acid to etch the aluminum nitride layer, so that the aluminum nitride layer is formed into a plurality of seeds arranged in an array;
epitaxially growing the gallium nitride to form a plurality of nanorods longitudinally on the seeds; and
epitaxially growing the gallium nitride to form a transversal film;
wherein the film covers horizontally on upper surfaces of the nanorods to form a substantial plane.

9. The method according to claim 8, wherein the substrate is a silicon substrate, a sapphire substrate, a gallium nitride substrate or a silicon carbide substrate.

10. The method according to claim 9, wherein a pitch between the seeds arranged in the array ranges from 100 to 300 nm.
